(19) United States
(12) Patent Application Publication
(10) Pub. No.: US 2018/0158968 A1
(43) Pub. Date: Jun. 7, 2018

(54) SOLAR CELL AND METHOD OF MANUFACTURING THE SAME

(71) Applicant: LG ELECTRONICS INC., Seoul (KR)

(72) Inventors: Daeyong Lee, Seoul (KR); Junyong Ahn, Seoul (KR)

(73) Assignee: LG ELECTRONICS INC., Seoul (KR)

(21) Appl. No.: 15/830,693

(22) Filed: Dec. 4, 2017

(30) Foreign Application Priority Data
Dec. 5, 2016 (KR) 10-2016-0164558
Apr. 26, 2017 (KR) 10-2017-0053781
Nov. 28, 2017 (KR) 10-2017-0160445

(51) Int. Cl. H01L 31/0236; H01L 31/18; H01L 31/0224; H01L 31/0216

(52) U.S. Cl. CPC H01L 31/02363; H01L 31/1804; H01L 31/02168; H01L 31/022425; H01L 31/02167; H01L 31/1864

(57) ABSTRACT

A solar cell and a method of manufacturing the same are discussed. The method of manufacturing the solar cell includes forming a dopant layer on one surface of a semiconductor substrate, selectively etching at least a portion of the dopant layer positioned in a first area of the semiconductor substrate, performing a thermal processing operation on the semiconductor substrate to form a conductive region, removing the dopant layer remaining in the one surface of the semiconductor substrate, forming first electrodes on a second area of the semiconductor substrate, and forming second electrodes on a surface opposite the one surface of the semiconductor substrate. In the thermal processing operation, a lightly doped region is formed in the first area, and a heavily doped region is formed in the second area.

### CROSS-REFERENCE TO RELATED APPLICATIONS

This application claims priority to, and the benefit of, Korean Patent Application No. 10-2016-0164558 filed in the Korean Intellectual Property Office on Dec. 5, 2016, Korean Patent Application No. 10-2017-0053781 filed in the Korean Intellectual Property Office on Apr. 26, 2017, and Korean Patent Application No. 10-2017-0160445 filed in the Korean Intellectual Property Office on Nov. 28, 2017, the entire contents of all these applications are incorporated herein by reference in its entirety.

### BACKGROUND OF THE INVENTION

### Field of the Invention

Embodiments of the invention relate to a solar cell and a method of manufacturing the same.

### Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy are attracting attention because of availability of ample energy resources and have no problem of environmental pollution.

A solar cell generally includes a substrate and an emitter region formed of semiconductors which respectively have different conductivity types, for example, a p-type and an n-type, and electrodes respectively connected to the substrate and the emitter region of the different conductivity types. In this instance, the substrate and the emitter region form a p-n junction.

When light is incident on the solar cell, a plurality of electron-hole pairs are produced in the semiconductors and are separated into electrons and holes by the incident light. The electrons move to the n-type semiconductor, for example, the emitter region, and the holes move to the p-type semiconductor, for example, the substrate. Then, the electrons and the holes are collected by the electrodes electrically connected to the substrate and the emitter region. The electrodes are connected to each other using electric wires to thereby obtain electric power.

A related art solar cell adopted a selective emitter structure in order to further improve a contact resistance between a semiconductor substrate and electrodes. In the related art solar cell, a heavily doped region was formed between the semiconductor substrate and the electrodes, and a lightly doped region was formed in an area of the semiconductor substrate in which the electrode is not formed.

Further, the related art solar cell used a laser to form the selective emitter structure. However, when the laser was used, an uneven structure formed at a front surface of the semiconductor substrate was damaged by the laser. Hence, there was a problem that a light absorptance of the semiconductor substrate was reduced.

### SUMMARY OF THE INVENTION

Embodiments of the invention provide a solar cell and a method of manufacturing the same.

In one aspect, there is provided a method of manufacturing a solar cell including a dopant layer forming operation of entirely forming a dopant layer containing impurities on one surface of a semiconductor substrate having textured portions; a selective etching operation of selectively etching at least a portion of the dopant layer positioned in a first area of the one surface of the semiconductor substrate from among the entire one surface of the semiconductor substrate, the first area being an area which will lack first electrodes; a thermal processing operation of performing a thermal processing on the semiconductor substrate to form a conductive region containing the impurities; a remaining dopant layer removing operation of removing the dopant layer remaining on the one surface of the semiconductor substrate; a first electrode forming operation of forming the first electrodes on a second area of the one surface of the semiconductor substrate from among the entire one surface of the semiconductor substrate, the second area being an area that excludes the first area; and a second electrode forming operation of forming second electrodes on a surface opposite the one surface of the semiconductor substrate, wherein the thermal processing operation includes forming a lightly doped region, which is doped with the impurities at a low concentration, in the first area of the semiconductor substrate and forming a heavily doped region, which is doped with the impurities at a high concentration higher than the low concentration of the lightly doped region of the first area, in the second area of the semiconductor substrate.

A thickness of the dopant layer formed in the dopant layer forming operation may be 40 nm to 80 nm.

An etching depth of the dopant layer etched in the selective etching operation may be greater than a half of a thickness of the dopant layer and may be less than the thickness of the dopant layer.

The selective etching operation may include using a laser to selectively etch the dopant layer positioned in the first area.

For example, in the selective etching operation, the dopant layer positioned in the first area may be entirely etched.

However, unlike this, the selective etching operation may include etching the dopant layer positioned in the first area to form a plurality of etched portions that are spaced apart from one another in a first direction.

In this instance, the thermal processing operation may include forming lightly doped regions to correspond to the plurality of etched portions formed by etching the dopant layer in the first area, the lightly doped regions being spaced apart from one another in the first direction; and forming a heavily doped region to correspond to a remaining portion of the dopant layer excluding the plurality of etched portions, the heavily doped region extending in a second direction intersecting the first direction.

For example, wherein a first direction etching width of each of the plurality of etched portions formed by etching the dopant layer in the selective etching operation may be greater than ¼ of a distance between the first electrodes and may be less than two times the distance between the first electrodes.

Further, a first direction etching gap of each of the plurality of etched portions formed by etching the dopant layer in the selective etching operation may be greater than ¼ of a width of the first electrodes and may be less than the distance between the first electrodes.

The first area and the second area may be extended in the first direction and alternately positioned in the second direction.

The remaining dopant layer removing operation may be performed by entirely forming an etch stop layer on the opposite surface of the one surface of the semiconductor substrate and then immersing the semiconductor substrate in an etchant.

The etchant used in the remaining dopant layer removing operation may be a dilute hydrogen fluoride (HF) solution.

The second area may extend in the first direction and the second direction intersecting the first direction. In the first electrode forming operation, the first electrodes may be formed in the second area extending in the first direction and may not be formed in the second area extending in the second direction.

In another aspect, there is provided a solar cell including a semiconductor substrate having textured portions on one surface; a first conductive region formed at the one surface of the semiconductor substrate and doped with impurities of a first conductivity type or a second conductivity type, the first conductive region including a lightly doped region doped with the impurities of the first conductivity type or the second conductivity type at a low concentration and a heavily doped region doped with the impurities of the first conductivity type or the second conductivity type at a high concentration higher than the low concentration of the lightly doped region; first electrodes connected to the heavily doped region of the first conductive region; and second electrodes connected to a surface opposite the one surface of the semiconductor substrate. The semiconductor substrate includes a first area which lacks the first electrodes and a second area in which the first electrodes are positioned. The lightly doped region and the heavily doped region are positioned in each first area, and the heavily doped region is positioned in each second area. The first electrodes extend in a first direction in each second area and are connected to the heavily doped region positioned in each second area. The lightly doped region and the heavily doped region positioned in the first area are alternately positioned in the first direction and extend in a second direction intersecting the first direction.

A first direction width of the lightly doped region positioned in the first area may be greater than ¼ of a distance between the first electrodes and may be less than two times the distance between the first electrodes.

A first direction width of the heavily doped region positioned in the first area may be greater than ¼ of a width of the first electrodes and may be less than a distance between the first electrodes.

The first direction width of the lightly doped region positioned in the first area may be equal to or greater than the first direction width of the heavily doped region positioned in the first area.

The solar cell may further include a second conductive region containing impurities of a conductivity type opposite a conductivity type of the impurities of the first conductivity type or the second conductivity type doped on the first conductive region at the opposite surface of the one surface of the semiconductor substrate.

The solar cell may further include a control passivation layer formed between the second conductive region and the semiconductor substrate, the control passivation layer including a dielectric material. A thickness of the control passivation layer may be 0.5 nm to 2.5 nm.

The method of manufacturing the solar cell according to embodiments of the invention can prevent the textured portions formed on the surface of the semiconductor substrate from being damaged by selectively etching a portion of the dopant layer on the semiconductor substrate to form the conductive region including the lightly doped region and the heavily doped region, thereby further improving efficiency of the solar cell.

Further, the solar cell according to embodiments of the invention can more smoothly move carriers by forming the heavily doped region in a non-formation area of the first electrode to be extended in a direction intersecting an extension direction of the first electrode.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1A and 1B illustrate an example of a solar cell manufactured in accordance with a manufacturing method according to an embodiment of the invention;

FIG. 2 illustrates another example of a solar cell manufactured in accordance with a manufacturing method according to an embodiment of the invention;

FIG. 3 is a flow chart illustrating a method of manufacturing a solar cell according to a first embodiment of the invention;

FIGS. 4 to 10 illustrate in detail the flow chart illustrated in FIG. 3;

FIGS. 11 and 12 illustrate another structure of a solar cell that can be manufactured using a method of manufacturing a solar cell according to a first embodiment of the invention;

FIG. 13 illustrates an example of a solar cell manufactured using a method of manufacturing a solar cell according to a second embodiment of the invention;

FIG. 14 is an enlarged plan view of a portion “K” shown in FIG. 13; and

FIG. 15 illustrates a selective etching method in a method of manufacturing a solar cell according to a second embodiment of the invention.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein. Wherever possible, the same reference numbers will be used throughout the drawings to refer to the same or like parts. It will be noted that a detailed description of known arts will be omitted if it is determined that the detailed description of the known arts can obscure the embodiments of the invention.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on other element, it may be on the entire surface of the other element and may not be on a portion of an edge of the other element.

In the following description, “front surface” may be one surface of a semiconductor substrate on which light is directly incident, and “back surface” may be a surface opposite the one surface of the semiconductor substrate on which light is not directly incident or reflective light may be incident.

In the following description, the fact that any two values are the same indicates that the two values are the same within a margin of error of 10%.

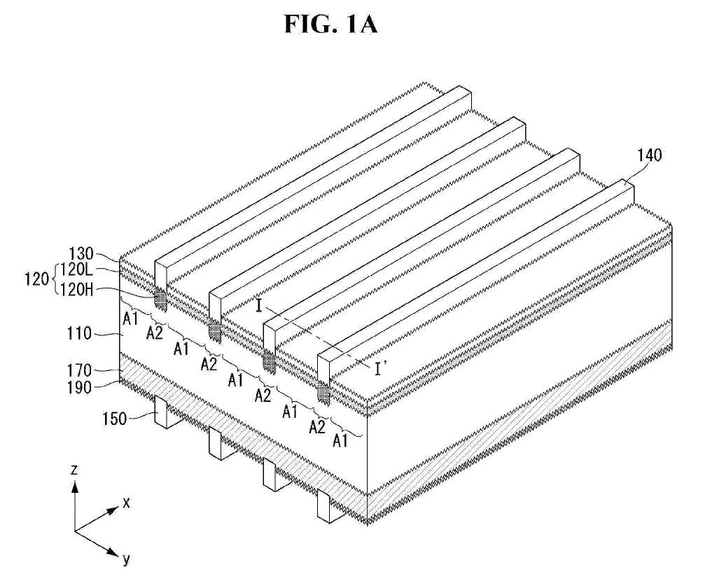

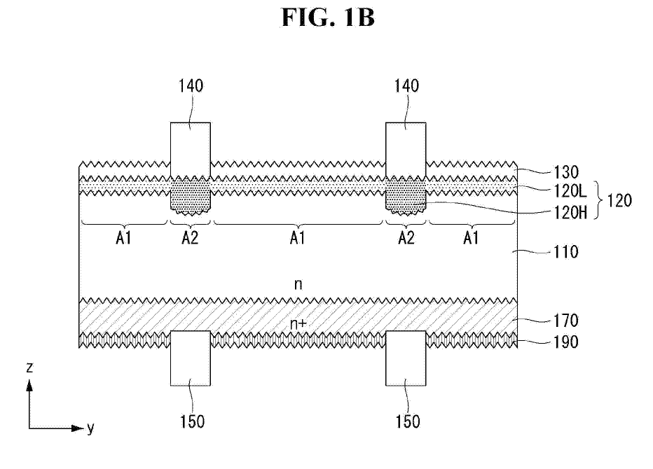

Embodiments of the invention will be described with reference to FIGS. 1A to 15.

FIGS. 1A and 1B illustrate an example of a solar cell manufactured in accordance with a manufacturing method according to an embodiment of the invention.

More specifically, FIG. 1A is a partial perspective view illustrating an example of a solar cell according to an embodiment of the invention, and FIG. 1B is a partial cross-sectional view of the solar cell shown in FIG. 1A.

As shown in FIG. 1A, an example of a solar cell according to an embodiment of the invention may include a semiconductor substrate 110, a first conductive region 120, an anti-reflection layer 130, a second conductive region 170, a back passivation layer 190, a first electrode 140, and a second electrode 150.

FIG. 1A illustrates that the solar cell according to the embodiment of the invention includes the anti-reflection layer 130 and the back passivation layer 190, by way of example. However, unlike FIG. 1A, the anti-reflection layer 130 and the back passivation layer 190 may be omitted in the embodiment of the invention, if desired or necessary.

However, when the solar cell includes the anti-reflection layer 130 and the back passivation layer 190, efficiency of the solar cell can be further improved. Thus, the embodiment of the invention is described using the solar cell including the anti-reflection layer 130 and the back passivation layer 190 as an example.

The semiconductor substrate 110 may be formed of at least one of single crystal silicon and polycrystalline silicon each containing impurities of a first conductivity type or a second conductivity type. For example, the semiconductor substrate 110 may be formed of a single crystal silicon wafer.

The semiconductor substrate 110 may contain impurities of the first conductivity type or impurities of the second conductivity type. In embodiments disclosed herein, the impurities of the first conductivity type may be impurities of an n-type or a p-type, and the impurities of the second conductivity type may be impurities of a conductivity type opposite the first conductivity type.

For example, when the first conductivity type is the p-type, the second conductivity type may be the n-type. On the contrary, when the first conductivity type is the n-type, the second conductivity type may be the p-type.

In the following description, an embodiment in which the first conductivity type is the p-type, the second conductivity type is the n-type, and the semiconductor substrate 110 contains impurities of the second conductivity type, i.e., n-type impurities will be described as an example.

When the semiconductor substrate 110 is of the p-type, the semiconductor substrate 110 may be doped with impurities of a group III element such as boron (B), gallium (Ga), and indium (In). Alternatively, when the semiconductor substrate 110 is of the n-type, the semiconductor substrate 110 may be doped with impurities of a group V element such as phosphorus (P), arsenic (As), and antimony (Sb).

In the following description, embodiments of the invention are described using an example where impurities contained in the semiconductor substrate 110 are impurities of the second conductivity type and are n-type impurities. However, embodiments of the invention are not limited thereto.

A front surface and a back surface of the semiconductor substrate 110 may be an uneven surface having a plurality of texturing uneven portions or having uneven characteristics. Thus, the first conductive region 120 positioned at the front surface of the semiconductor substrate 110 may have an uneven surface, and the second conductive region 170 positioned at the back surface of the semiconductor substrate 110 may have an uneven surface.

In embodiments disclosed herein, “texturing uneven portion” or textured portion indicates an uneven portion formed on the surface of the solar cell in order to reduce an amount of reflected light and may have, for example, a pyramid shape.

Hence, an amount of light reflected from the front surface of the semiconductor substrate 110 can decrease, and an amount of light incident on the inside of the semiconductor substrate 110 can increase.

The first conductive region 120 positioned at the front surface of the semiconductor substrate 110 may contain impurities of the first conductivity type or the second conductivity type. For example, the first conductive region 120 may contain impurities of the first conductivity type, i.e., p-type impurities.

In the following description, embodiments of the invention are described using an example where the first conductive region 120 contains impurities of the first conductivity type. However, embodiments of the invention are not limited thereto. For example, the first conductive region 120 may contain impurities of the second conductivity type.

Thus, when the semiconductor substrate 110 contains impurities of the second conductivity type, the first conductive region 120 may form a p-n junction together with the semiconductor substrate 110 and may serve as an emitter region.

In the following description, embodiments of the invention are described using an example where the first conductive region 120 serves as the emitter region.

Thus, when the semiconductor substrate 110 is of the n-type and the first conductive region 120 is of the p-type, holes may move to the first conductive region 120 and electrons may move to the back surface of the semiconductor substrate 110.

The first conductive region 120 may be formed by diffusing impurities of the second conductivity type into the front surface of the semiconductor substrate 110. In this instance, the first conductive region 120 may be formed of the same silicon material as the semiconductor substrate 110.

For example, when the semiconductor substrate 110 is formed of a wafer of a single crystal silicon material, the first conductive region 120 may be formed of a single crystal silicon material. When the semiconductor substrate 110 is formed of a wafer of a polycrystalline silicon material, the first conductive region 120 may be formed of a polycrystalline silicon material.

As shown in FIGS. 1A and 1B, the first conductive region 120 may include a lightly doped region 120L which is formed in a first area A1 of the entire front surface of the semiconductor substrate 110 and is doped with impurities at a low concentration, and a heavily doped region 120H which is formed in a second area A2 of the semiconductor substrate 110 and is doped with impurities at a concentration higher than the lightly doped region 120L of the first area A1.

In embodiments disclosed herein, the first area A1 of the semiconductor substrate 110 indicates an area in which the first electrode 140 is not positioned, and the second area A2 of the semiconductor substrate 110 indicates an area in which the first electrode 140 is positioned.

The anti-reflection layer 130 is positioned on the first conductive region 120. The anti-reflection layer 130 may be formed of at least one of aluminum oxide (AlOx), silicon nitride (SiNx), silicon oxide (SiOx), and silicon oxynitride (SiOxNy) and may have a single-layered structure or a multi-layered structure.

FIGS. 1A and 1B illustrate that the anti-reflection layer 130 has the single-layered structure, by way of example. However, embodiments of the invention are not limited thereto.

The anti-reflection layer 130 can reduce a reflectance of light incident on the solar cell and increase selectivity of a predetermined wavelength band, thereby increasing the efficiency of the solar cell.

The first electrode 140 may pass through the anti-reflection layer 130 and may be directly connected to the first conductive region 120. Namely, the first electrode 140 may be electrically connected to the first conductive region 120.

The first electrode 140 may collect carriers moving to the first conductive region 120.

The carriers collected by the first electrode 140 may be connected to another solar cell by an interconnector and may be output to an external device.

The first electrode 140 may be formed of at least one conductive metal material. For example, the first electrode 140 may be formed of at least one of nickel (Ni), copper (Cu), silver (Ag), aluminum (Al), tin (Sn), zinc (Zn), indium (In), titanium (Ti), gold (Au), and a combination thereof. Alternatively, other conductive metal materials may be used.

The first electrode 140 may be formed by applying the conductive metal material of a paste state on the anti-reflection layer 130 after forming the anti-reflection layer 130 on the front surface of the semiconductor substrate 110 and performing a thermal processing to fire the paste so that the paste passes through the anti-reflection layer 130 and is connected to the first conductive region 120.

As shown in FIGS. 1A and 1B, the first electrode 140 may include a plurality of finger electrodes extended in a first direction x (for example, x-axis direction). The first electrode 140 may further include a connection electrode that connects the plurality of finger electrodes and is extended in a second direction y (for example, y-axis direction) intersecting the first direction x, in addition to the finger electrodes.

The second conductive region 170 positioned at the back surface of the semiconductor substrate 110 may be formed of a polycrystalline silicon material containing impurities of a conductivity type opposite a conductivity type of impurities contained in the first conductive region 120.

For example, the second conductive region 170 may contain impurities (i.e., n-type impurities) of the second conductivity type at a concentration higher than the semiconductor substrate 110.

Hence, the second conductive region 170 may serve as a back surface field (BSF) region.

As shown in FIGS. 1A and 1B, the second conductive region 170 may be formed at the back surface of the semiconductor substrate 110 while directly contacting the semiconductor substrate 110.

FIGS. 1A and 1B illustrate that the second conductive region 170 is entirely formed at the back surface of the semiconductor substrate 110 while directly contacting the back surface of the semiconductor substrate 110 and is formed of a polycrystalline silicon material, by way of example. However, embodiments of the invention are not limited thereto. For example, the second conductive region 170 may be formed by doping impurities into the back surface of the semiconductor substrate 110 and may be formed of the same silicon material as the semiconductor substrate 110.

As shown in FIGS. 1A and 1B, the back passivation layer 190 may be entirely formed on a remaining portion excluding a formation area of the second electrode 150 from a back surface of the second conductive region 170.

The back passivation layer 190 may be formed of a dielectric material and may be configured as a single layer or a plurality of layers. The back passivation layer 190 may have specific fixed charges in consideration of a polarity of the second conductive region 170.

The back passivation layer 190 may be formed of at least one of silicon carbide (SiC), silicon oxide (SiOx), silicon nitride (SiNx), hydrogenerated SiNx, aluminum oxide (AlOx), silicon oxynitride (SiON), or hydrogenerated SiON.

The back passivation layer 190 may perform a passivation function on the back surface of the second conductive region 170.

The second electrode 150 may pass through the back passivation layer 190 and may be electrically connected to the second conductive region 170.

The second electrode 150 may collect carriers moving to the second conductive region 170.

So far, FIGS. 1A and 1B illustrate that the semiconductor substrate 110 contains n-type impurities, the first conductive region 120 contains p-type impurities and serves as the emitter region, and the second conductive region 170 contains n-type impurities and serves as the back surface field region, by way of example.

However, embodiments of the invention are not limited to the above-described structure. Unlike the above-described structure, the semiconductor substrate 110 may contain p-type impurities, the first conductive region 120 may contain p-type impurities and serve as a front surface field region, and the second conductive region 170 may contain n-type impurities and serves as the back surface field region.

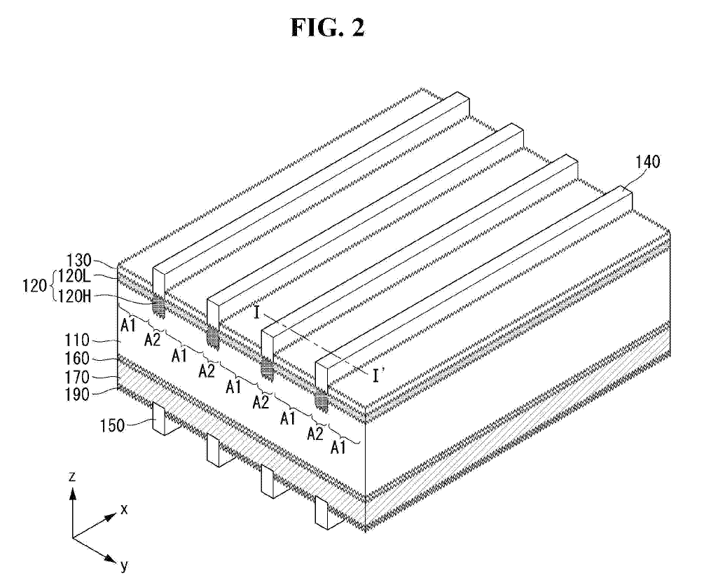

FIG. 2 illustrates another example of a solar cell manufactured in accordance with a manufacturing method according to an embodiment of the invention.

In the following description, a description of structures and components identical or equivalent to those illustrated in FIGS. 1A and 1B is omitted in FIG. 2, and a difference between them will be mainly described.

As shown in FIG. 2, another example of a solar cell manufactured in accordance with an embodiment of the invention may further include a control passivation layer 160 between a semiconductor substrate 110 and a second conductive region 170.

For example, as shown in FIG. 2, the control passivation layer 160 may be formed between the semiconductor substrate 110 and the second conductive region 170 and may be positioned on an entire back surface of the semiconductor substrate 110 excluding an edge of the back surface of the semiconductor substrate 110.

The control passivation layer 160 can pass carriers produced in the semiconductor substrate 110 toward the second conductive region 170 and perform a passivation function on the back surface of the semiconductor substrate 110. Further, the control passivation layer 160 can increase an open-circuit voltage Voc of the solar cell.

The control passivation layer 160 may be formed of a dielectric material including silicon carbide (SiC) or silicon oxide (SiOx) having strong durability even at a high temperature equal to or higher than 600° C. Other materials may be used. For example, silicon nitride (SiNx), hydrogenerated SiNx, aluminum oxide (AlOx), silicon oxynitride (SiON), or hydrogenerated SiON may be used for the control passivation layer 160.

A thickness of the control passivation layer 160 may be 0.5 nm to 2.5 nm. The thickness of the control passivation layer 160 may be an optimum value for the purpose of performing the passivation function, etc. of the control passivation layer 160.

The control passivation layer 160 may be formed through an oxidation process, a low pressure chemical vapor deposition (LPCVD) process, or a plasma enhanced chemical vapor deposition (PECVD) process.

When the control passivation layer 160 is included as described above, the second conductive region 170 may be formed on a back surface of the control passivation layer 160 as shown in FIG. 2.

More specifically, as shown in FIG. 2, the second conductive region 170 is not positioned inside the back surface of the semiconductor substrate 110 or does not directly contact the back surface of the semiconductor substrate 110; and is formed on the back surface of the semiconductor substrate 110 to be spaced apart from the semiconductor substrate 110 with the control passivation layer 160 interposed therebetween and is made of a polycrystalline silicon material. In this instance, the open-circuit voltage Voc of the solar cell can be further improved.

Because the second conductive region 170 is not formed inside the semiconductor substrate 110 and is formed outside the semiconductor substrate 110, a thermal damage of the semiconductor substrate 110 in a process for forming the second conductive region 170 can be minimized. Hence, a reduction in characteristics of the semiconductor substrate 110 can be prevented.

Accordingly, efficiency of the solar cell shown in FIG. 2 can be further improved. So far, examples of the solar cell manufactured in accordance with the manufacturing method according to the embodiment of the invention were described. Hereinafter, examples of a method of manufacturing the solar cell according to the embodiment of the invention will be described.

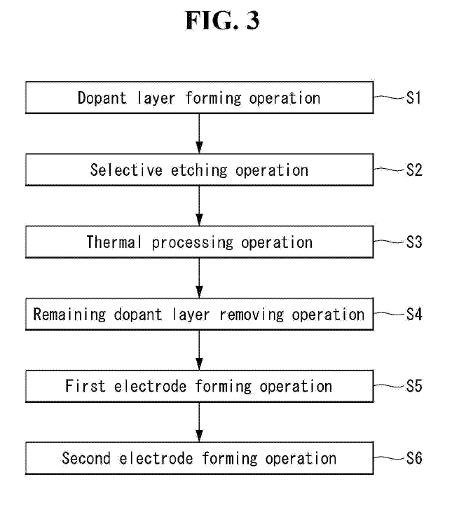

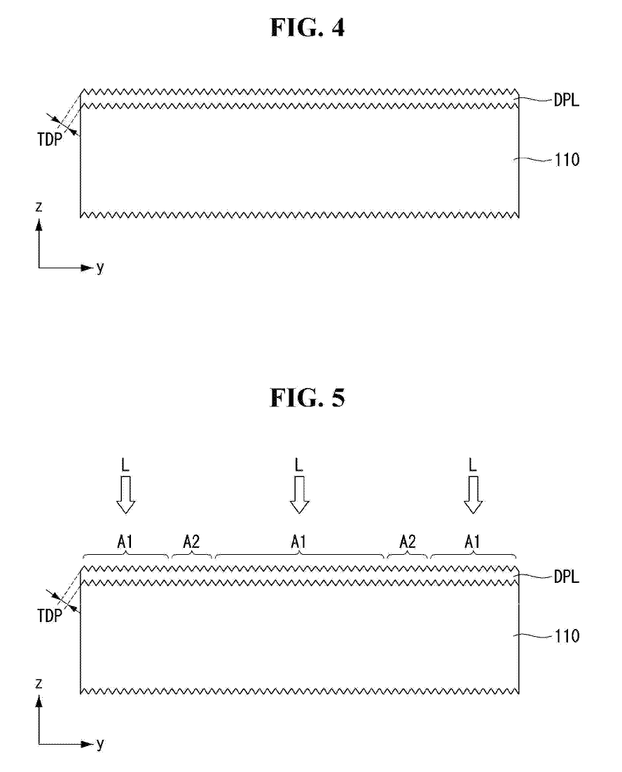

FIG. 3 is a flow chart illustrating a method of manufacturing a solar cell according to a first embodiment of the invention. FIGS. 4 to 10 illustrate in detail the flow chart illustrated in FIG. 3.

As shown in FIG. 3, a method of manufacturing a solar cell according to the first embodiment of the invention includes a dopant layer forming operation S1, a selective etching operation S2, a thermal processing operation S3, a remaining dopant layer removing operation S4, a first electrode forming operation S5, and a second electrode forming operation S6.

As shown in FIG. 4, the dopant layer forming operation S1 may entirely form a dopant layer DPL containing impurities of a first conductivity type or a second conductivity type on one surface of a semiconductor substrate 110 having texturing uneven portions.

The one surface of the semiconductor substrate 110 may be a surface of the semiconductor substrate 110 on which the texturing uneven portions are formed. For example, when the texturing uneven portions are formed on a front surface of the semiconductor substrate 110, the one surface of the semiconductor substrate 110 may be the front surface.

Accordingly, as described above with reference to FIGS. 1A and 1B, when a first conductive region 120 is to be formed at the front surface of the semiconductor substrate 110, the dopant layer forming operation S1 may form a borosilicate glass (BSG) layer containing impurities, for example, boron (B) of the first conductivity type as the dopant layer DPL at the front surface of the semiconductor substrate 110.

Alternatively, unlike FIGS. 1A and 1B, when a second conductive region 170 is to be formed at the front surface of the semiconductor substrate 110, the dopant layer forming operation S1 may form a phosphosilicate glass (PSG) layer containing impurities, for example, phosphorus (P) of the second conductivity type as the dopant layer DPL at the front surface of the semiconductor substrate 110.

In the following description, embodiments of the invention are described using an example where the BSG layer containing impurities of the first conductivity type is used as the dopant layer DPL.

A thickness TDP of the dopant layer DPL formed in the dopant layer forming operation S1 may be 40 nm to 60 nm so that the first conductive region 120 positioned at the front surface of the semiconductor substrate 110 has a heavily doped region.

In the dopant layer forming operation S1, the dopant layer DPL may be formed using a chemical vapor deposition (CVD) method.

Next, as shown in FIG. 5, the selective etching operation S2 may selectively etch at least a portion of the dopant layer DPL positioned in a first area A1 in which a first electrode 140 is not formed in the entire one surface of the semiconductor substrate 110.

In embodiments disclosed herein, the first area A1 may indicate an area in which the first electrode 140 is not formed in the entire one surface of the semiconductor substrate 110, and a second area A2 may indicate an area in which the first electrode 140 is formed in the entire one surface of the semiconductor substrate 110.

Accordingly, for example, when the first electrode 140 is configured as only finger electrodes extended in a first direction x as shown in FIGS. 1A and 1B, the first areas A1 and the second areas A2 may be extended in the first direction x and may be alternately positioned in a second direction y intersecting the first direction x.

However, when the first electrode 140 includes a connection electrode as well as the finger electrodes, the second areas A2 may be extended in the second direction y as well as the first direction x. In the following description, embodiments of the invention are described using an example where the first electrode 140 includes only the finger electrodes.

Accordingly, as shown in FIG. 5, the selective etching operation S2 may selectively etch at least a portion of the dopant layer DPL positioned in the first area A1.

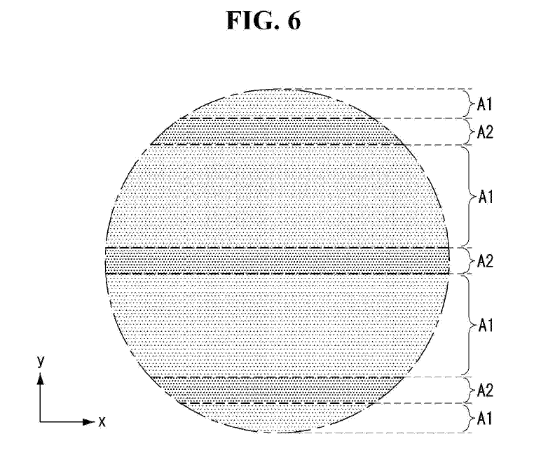

For example, as shown in FIG. 6 that schematically illustrates a plane of FIG. 5, the dopant layer DPL positioned in the first area A1 of the entire front surface of the semiconductor substrate 110 may be etched to be extended in the first direction x, and the dopant layer DPL positioned in the second area A2 of the semiconductor substrate 110 may not be etched.

In this instance, only the first area A1 may be selectively etched by a laser, and the dopant layer DPL positioned in the first area A1 may be entirely etched.

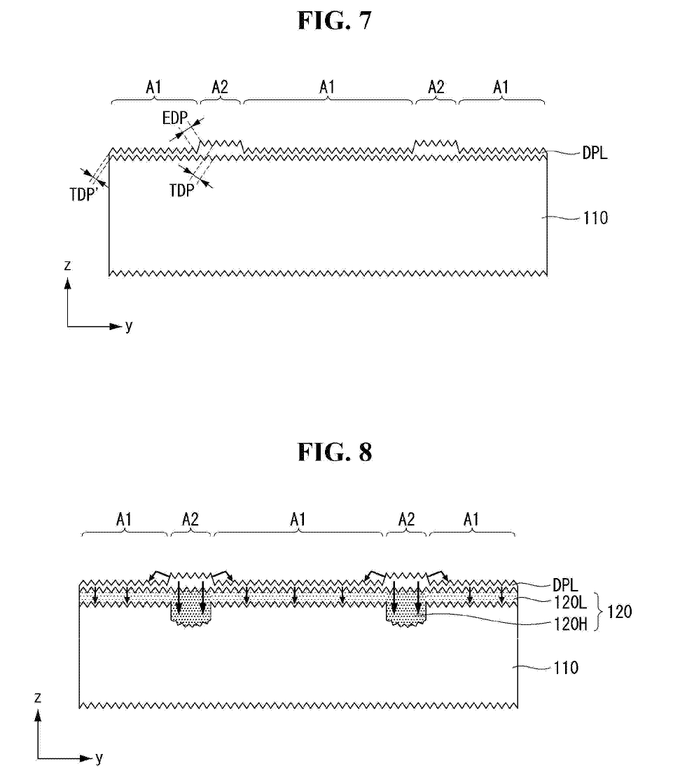

As shown in FIG. 7, an etching depth EDP of the dopant layer DPL in the selective etching operation S2 may be greater than a half of the thickness TDP of the dopant layer DPL and may be less than the thickness TDP of the dopant layer DPL.

For example, after the dopant layer DPL of the first areas A1 is etched, a thickness TDP′ of the remaining dopant layer DPL which is not etched may be greater than zero and less than 30 nm.

Hence, the texturing uneven portions formed on the one surface of the semiconductor substrate 110 can be prevented from being damaged.

In a related art, when a selective emitter structure was formed using a laser, a lightly doped region was formed at a surface of a semiconductor substrate, and then the laser was selectively irradiated onto an anti-reflection layer positioned in a portion of the surface of the semiconductor substrate in a state where the anti-reflection layer was formed on the lightly doped region, thereby removing the anti-reflection layer. Impurities were additionally diffused into the surface of the semiconductor substrate exposed by removing the anti-reflection layer to form a heavily doped region.

However, in this instance, the laser not only removed the anti-reflection layer but also damaged texturing uneven portions of the semiconductor substrate during the irradiation of the laser. Hence, reflectivity of the semiconductor substrate was deteriorated, and the semiconductor substrate was damaged.

However, in the embodiment of the invention, the laser is not irradiated in a state where an anti-reflection layer is formed, and the dopant layer is selectively etched by the laser in a state where the dopant layer is formed on the surface of the semiconductor substrate before the anti-reflection layer is formed. Hence, as shown in FIG. 7, the dopant layer is not completely removed and is selectively etched by the laser so that a portion of the dopant layer remains on the surface of the semiconductor substrate to as small a thickness as possible. As a result, the texturing uneven portions of the semiconductor substrate can be prevented from being damaged, and a reflectance and a transmittance of the front surface corresponding to a light receiving surface of the semiconductor substrate can be prevented from being deteriorated. An undoped silica glass (USG) layer not doped with impurities may be entirely deposited on the dopant layer DPL remaining on the first area A1 and the second area A2 of the semiconductor substrate 110, in order to prevent impurities from being diffused out of the dopant layer DPL in the subsequent thermal processing operation S3. However, the deposition of the USG layer is not necessarily required and may be omitted, if desired or necessary.

Next, in the thermal processing operation S3, the semiconductor substrate 110 on which the dopant layer DPL is formed may be driven in a thermal processing chamber and thermally processed.

As shown in FIG. 8, the thermal processing operation S3 may perform the thermal processing on the semiconductor substrate 110 and diffuse impurities contained in the dopant layer DPL into the semiconductor substrate 110, thereby forming a conductive region containing impurities of the first conductivity type or the second conductivity type.

Accordingly, when the dopant layer DPL contains impurities of the first conductivity type, the thermal processing operation S3 may form the first conductive region 120 at the one surface of the semiconductor substrate 110. Alternatively, when the dopant layer DPL contains impurities of the second conductivity type, the thermal processing operation S3 may form the second conductive region 170 at the one surface of the semiconductor substrate 110.

In the thermal processing operation S3, a lightly doped region 120L doped with impurities at a low concentration may be formed in the first area A1 of the semiconductor substrate 110, and a heavily doped region 120H doped with impurities at a concentration higher than the lightly doped region 120L of the first area A1 may be formed in the second area A2 of the semiconductor substrate 110.

More specifically, the lightly doped region 120L may be formed in the first area A1 of the semiconductor substrate 110 due to the relatively thin thickness TDP′ of the remaining dopant layer DPL. The heavily doped region 120H may be formed in the second area A2 of the semiconductor substrate 110 due to the relatively thick thickness TDP′ of the remaining dopant layer DPL.

If the dopant layer DPL positioned on the first area A1 of the semiconductor substrate 110 is completely etched in the selective etching operation S2, the USG layer may not be formed. Further, in the thermal processing operation S3, impurities of the dopant layer DPL remaining in the second area A2 of the semiconductor substrate 110 may be diffused into the first area A1 of the semiconductor substrate 110 through an inner space of the thermal processing chamber.

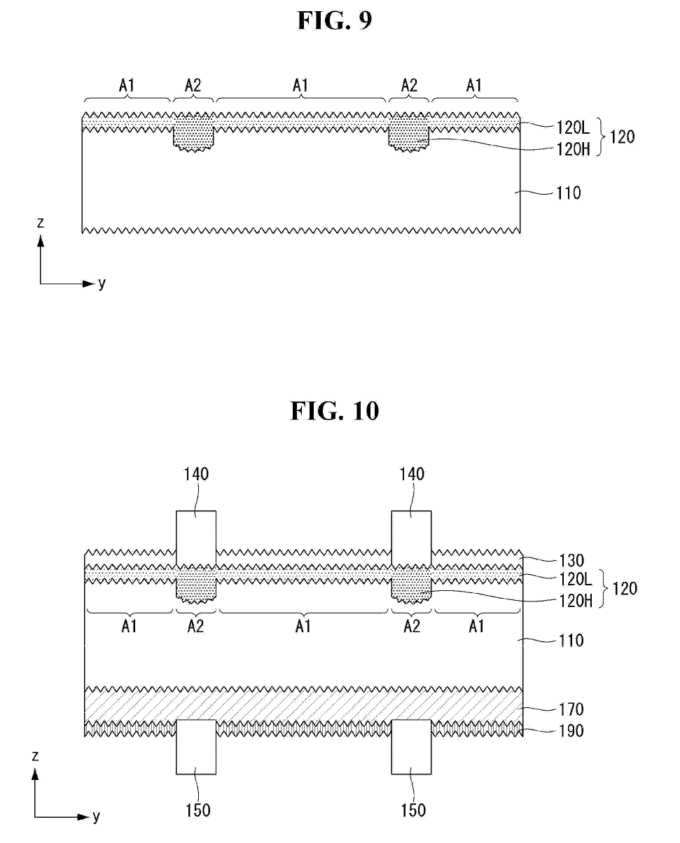

After the thermal processing operation S3, the remaining dopant layer removing operation S4 may be performed. Hence, as shown in FIG. 9, the dopant layer DPL remaining on the one surface of the semiconductor substrate 110 may be completely removed.

The remaining dopant layer removing operation S4 may be performed by entirely forming an etch stop layer on a surface opposite the one surface of the semiconductor substrate 110 and then immersing the semiconductor substrate 110 in an etchant, for example, a dilute hydrogen fluoride (HF) solution.

After the remaining dopant layer DPL is removed, the etch stop layer formed on the opposite surface of the semiconductor substrate 110 may be removed.

Next, as shown in FIG. 10, the second conductive region 170 and a back passivation layer 190 may be formed on the opposite surface of the semiconductor substrate 110. The first electrode forming operation S5 and the second electrode forming operation S6 may be performed in a state where an anti-reflection layer 130 is formed on the one surface of the semiconductor substrate 110.

The first electrode forming operation S5 may form a first electrode 140 on the second area A2 excluding the first area A1 from the entire one surface of the semiconductor substrate 110. The second electrode forming operation S6 may form a second electrode 150 on the opposite surface of the semiconductor substrate 110.

As a result, the solar cell shown in FIG. 10 can be manufactured.

As described above, the method of manufacturing the solar cell according to the first embodiment of the invention may selectively etch the dopant layer DPL positioned in the first area A1 when forming the conductive region including the lightly doped region 120L and the heavily doped region 120H at one surface of the semiconductor substrate 110 having the texturing uneven portions. In this instance, the dopant layer DPL may be etched so that the texturing uneven portions of the semiconductor substrate 110 are not damaged. Hence, the embodiment of the invention can minimize a contact resistance between the first electrode 140 and the conductive region while maximizing a light absorptance of the semiconductor substrate 110, and can maximize a short circuit current of the solar cell.

So far, the method of manufacturing the solar cell according to the first embodiment of the invention was described using an example where the second conductive region 170 is directly formed at the back surface of the semiconductor substrate 110.

However, the method of manufacturing the solar cell according to the first embodiment of the invention is not limited to the above-described structure.

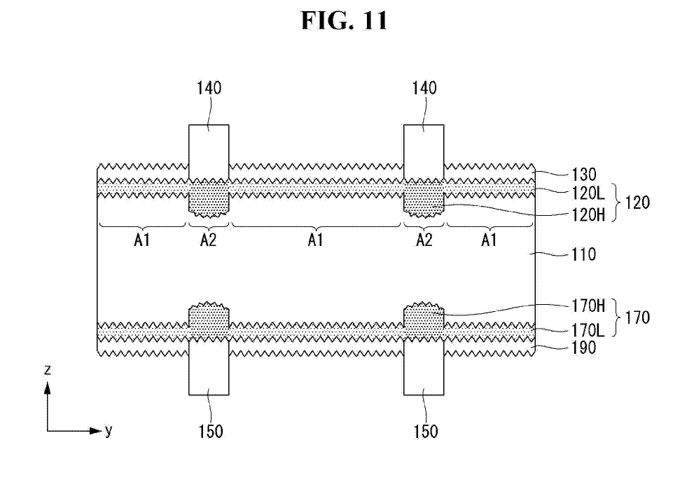

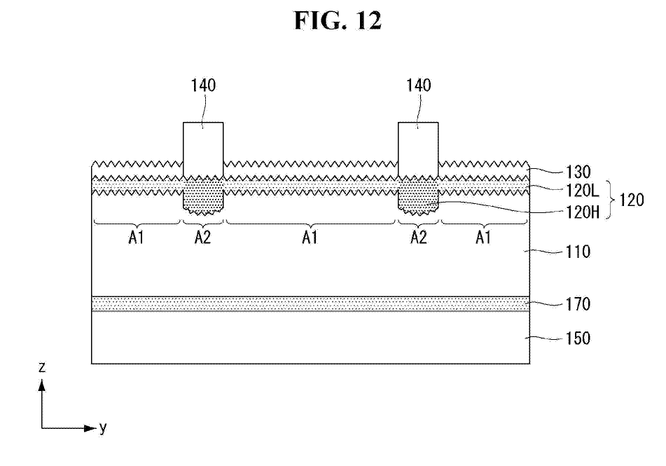

FIGS. 11 and 12 illustrate another structure of a solar cell that can be manufactured using the method of manufacturing the solar cell according to the first embodiment of the invention.

As shown in FIG. 11, the method of manufacturing the solar cell according to the first embodiment of the invention can be applied to even a solar cell in which a first conductive region 120 including a lightly doped region 120L and a heavily doped region 120H is positioned at a front surface of a semiconductor substrate 110, and a second conductive region 170 including a lightly doped region 170L and a heavily doped region 170H is positioned at a back surface of the semiconductor substrate 110. Thus, the first conductive region 120 and the second conductive region 170 can be formed in accordance with the operations illustrated in FIGS. 3 to 10.

Further, as shown in FIG. 12, the method of manufacturing the solar cell according to the first embodiment of the invention can be applied to even a solar cell in which a first conductive region 120 including a lightly doped region 120L and a heavily doped region 120H is positioned at a front surface of a semiconductor substrate 110, and a second conductive region 170 is entirely positioned at a back surface of the semiconductor substrate 110. Thus, the first conductive region 120 and the second conductive region 170 can be formed in accordance with the operations illustrated in FIGS. 3 to 10.

The method of manufacturing the solar cell according to the first embodiment of the invention was described using an example where the dopant layer DPL positioned in the first area A1, in which the first electrode 140 is not formed, is entirely etched in the selective etching operation S2. However, embodiments of the invention are not limited thereto. For example, the dopant layer DPL positioned in the first area A1 is not entirely etched and may be selectively etched to form a plurality of portions of the dopant layer DPL that are spaced apart from one another in the first area A1 in the first direction x.

In this instance, a formation pattern of the lightly doped region 120L and the heavily doped region 120H of the first conductive region 120 formed at the one surface of the semiconductor substrate 110 may be changed.

This will be described in detail below.

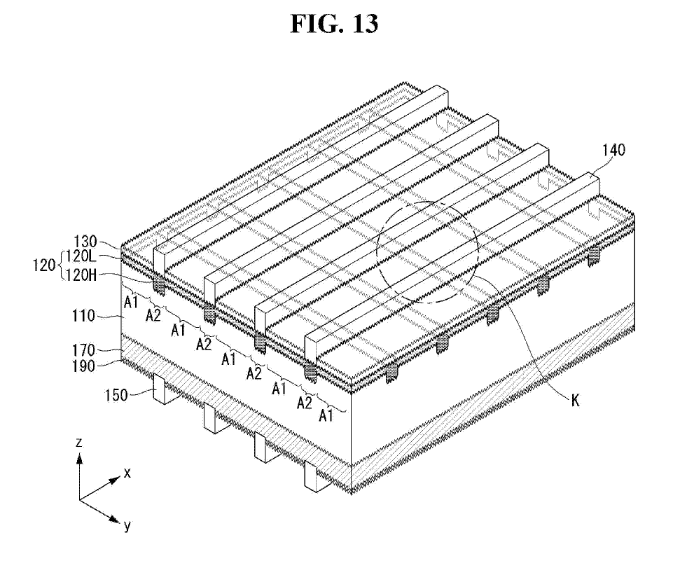

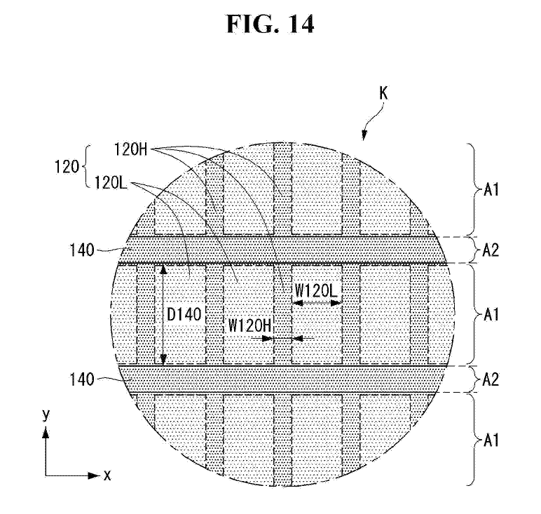

FIG. 13 illustrates an example of a solar cell manufactured using a method of manufacturing a solar cell according to a second embodiment of the invention. FIG. 14 is an enlarged plan view of a portion “K” shown in FIG. 13.

In the following description, a description of structures and components identical or equivalent to those illustrated in FIGS. 1A and 1B is omitted in FIGS. 13 and 14, and a difference between them will be mainly described.

As shown in FIG. 13, the solar cell manufactured using the manufacturing method according to the second embodiment of the invention is different from the solar cell shown in FIGS. 1A and 1B in that a lightly doped region 120L and a heavily doped region 120H are positioned in each first area A1 on which a first electrode 140 is not positioned.

More specifically, in the solar cell manufactured using the manufacturing method according to the second embodiment of the invention, the first electrode 140 may include a finger electrode extended in a first direction x in each second area A2, and a first conductive region 120 may include the lightly doped region 120L and the heavily doped region 120H in each first area A1 and may include the heavily doped region 120H in each second area A2.

Hence, the first electrode 140 positioned in the second area A2 may be connected to the heavily doped region 120H positioned in the second area A2.

As shown in FIG. 14, the lightly doped regions 120L and the heavily doped regions 120H may be alternately positioned in the first area A1 in the first direction x and may be extended in a second direction y intersecting the first direction x.

A first direction width W120L of the lightly doped region 120L positioned in the first area A1 may be greater than ¼ of a distance D140 between the first electrodes 140 and less than two times the distance D140 between the first electrodes 140.

Further, a first direction width W120H of the heavily doped region 120H positioned in the first area A1 may be greater than ¼ of a width of the first electrode 140 and less than the distance D140 between the first electrodes 140.

The first direction width W120L of the lightly doped region 120L positioned in the first area A1 may be equal to or greater than the first direction width W120H of the heavily doped region 120H positioned in the first area A1.

The solar cell shown in FIGS. 13 and 14 is configured such that the heavily doped region 120H is extended in the second direction y intersecting an extension direction of the first electrode 140 in the first area A1 on which the first electrode 140 is not positioned, thereby causing carriers collected by the lightly doped region 120L to move to the first electrode 140 through the heavily doped region 120H having a relatively low resistance. Hence, the efficiency of the solar cell can be further improved.

The methods of manufacturing the solar cell according to the first and second embodiments of the invention are entirely the same as each other, but they may differently implement an etching pattern of the dopant layer DPL positioned in the first area A1 in the selective etching operation S2.

The method of manufacturing the solar cell according to the second embodiment of the invention will be described below.

The method of manufacturing the solar cell according to the second embodiment of the invention may be substantially the same as the method of manufacturing the solar cell according to the first embodiment of the invention illustrated in FIGS. 3 to 10, except a selective etching operation.

Thus, the method of manufacturing the solar cell according to the second embodiment of the invention is described focusing on a selective etching method in the method of manufacturing the solar cell according to the first embodiment of the invention illustrated in FIG. 3.

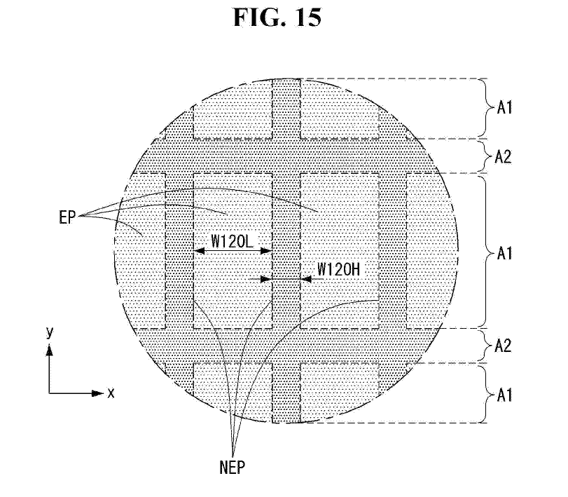

FIG. 15 illustrates a selective etching method in the method of manufacturing the solar cell according to the second embodiment of the invention.

As shown in FIG. 15, a selective etching method in the method of manufacturing the solar cell according to the second embodiment of the invention does not etch the dopant layer DPL positioned in the second area A2 of the semiconductor substrate 110 and may selectively etch the dopant layer DPL positioned in the first area A1 of the semiconductor substrate 110.

In this instance, the dopant layer DPL positioned in the first area A1 may be etched to form a plurality of portions EP that are spaced apart from one another in the first direction x. In FIG. 15, “NEP” denotes a non-etched portion of the dopant layer DPL.

In the selective etching operation S2, the dopant layer DPL may be etched so that a first direction etching width W120L of each of the plurality of portions EP formed by etching the dopant layer DPL is greater than ¼ of a distance D140 between the first electrodes 140 and is less than two times the distance D140 between the first electrodes 140.

Further, in the selective etching operation S2, a first direction etching gap W120H of each of the plurality of portions EP of the dopant layer DPL may be greater than ¼ of a width of the first electrode 140 and less than the distance D140 between the first electrodes 140.

In this instance, the first direction etching width W120L may be equal to or greater than the first direction etching gap W120H.

FIG. 15 illustrates that the first direction etching width W120L is greater than the first direction etching gap W120H, by way of example.

In the thermal processing operation S3, the lightly doped regions 120L that are spaced apart from one another in the first direction x may be formed in the plurality of portions EP formed by etching the dopant layer DPL of the first area A1. The heavily doped regions 120H extended in the second direction y may be formed in a remaining portion excluding the plurality of portions EP from the first area A1. As a result, the solar cell shown in FIGS. 13 and 14 can be manufactured.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a solar cell including first electrodes on one surface of a semiconductor substrate and second electrodes on a surface opposite the one surface of the semiconductor substrate, the method comprising:
a dopant layer forming operation of entirely forming a dopant layer containing impurities of a first conductivity type or a second conductivity type on the one surface of the semiconductor substrate having textured portions;
a selective etching operation of selectively etching at least a portion of the dopant layer positioned in a first area of the one surface of the semiconductor substrate from among the entire one surface of the semiconductor substrate, the first area being an area which will lack the first electrodes;
a thermal processing operation of performing a thermal processing on the semiconductor substrate and diffusing the impurities of the first conductivity type or the second conductivity type contained in the dopant layer into the semiconductor substrate to form a conductive region containing the impurities of the first conductivity type or the second conductivity type;
a remaining dopant layer removing operation of removing the dopant layer remaining on the one surface of the semiconductor substrate;
a first electrode forming operation of forming the first electrodes on a second area of the one surface of the semiconductor substrate from among the entire one surface of the semiconductor substrate, the second area being an area that excludes the first area; and
a second electrode forming operation of forming the second electrodes on the opposite surface of the semiconductor substrate,
wherein the thermal processing operation includes:
forming a lightly doped region, which is doped with the impurities of the first conductivity type or the second conductivity type at a low concentration, in the first area of the semiconductor substrate; and
forming a heavily doped region, which is doped with the impurities of the first conductivity type or the second conductivity type at a high concentration higher than the low concentration of the lightly doped region of the first area, in the second area of the semiconductor substrate.

2. The method of claim 1, wherein a thickness of the dopant layer formed in the dopant layer forming operation is 40 nm to 80 nm.

3. The method of claim 1, wherein an etching depth of the dopant layer etched in the selective etching operation is greater than a half of a thickness of the dopant layer and is less than the thickness of the dopant layer.

4. The method of claim 1, wherein the selective etching operation includes using a laser to selectively etch the dopant layer positioned in the first area.

5. The method of claim 1, wherein the selective etching operation includes entirely etching the dopant layer positioned in the first area.

6. The method of claim 1, wherein the selective etching operation includes etching the dopant layer positioned in the first area to form a plurality of etched portions that are spaced apart from one another in a first direction.

7. The method of claim 6, wherein the thermal processing operation includes:
forming lightly doped regions to correspond to the plurality of etched portions formed by etching the dopant layer in the first area, the lightly doped regions being spaced apart from one another in the first direction; and
forming a heavily doped region to correspond to a remaining portion of the dopant layer excluding the plurality of etched portions, the heavily doped region extending in a second direction intersecting the first direction.

8. The method of claim 6, wherein a first direction etching width of each of the plurality of etched portions formed by etching the dopant layer in the selective etching operation is greater than ¼ of a distance between the first electrodes and is less than two times the distance between the first electrodes.

9. The method of claim 6, wherein a first direction etching gap of each of the plurality of etched portions formed by etching the dopant layer in the selective etching operation is greater than ¼ of a width of the first electrodes and is less than a distance between the first electrodes.

10. The method of claim 1, wherein the first area and the second area are extended in a first direction and are alternately positioned in a second direction intersecting the first direction.

11. The method of claim 1, wherein the remaining dopant layer removing operation is performed by entirely forming an etch stop layer on the opposite surface of the one surface of the semiconductor substrate and then immersing the semiconductor substrate in an etchant.

12. The method of claim 11, wherein the etchant used in the remaining dopant layer removing operation is a dilute hydrogen fluoride (HF) solution.

13. The method of claim 1, wherein the second area extends in a first direction and a second direction intersecting the first direction, and
wherein in the first electrode forming operation, the first electrodes are formed in the second area extending in the first direction and are not formed in the second area extending in the second direction.

14. A solar cell comprising:
a semiconductor substrate having textured portions on one surface;
a first conductive region formed at the one surface of the semiconductor substrate and doped with impurities of a first conductivity type or a second conductivity type, the first conductive region including a lightly doped region doped with the impurities of the first conductivity type or the second conductivity type at a low concentration and a heavily doped region doped with the impurities at a high concentration higher than the low concentration of the lightly doped region;
first electrodes connected to the heavily doped region of the first conductive region; and
second electrodes connected to a surface opposite the one surface of the semiconductor substrate,
wherein the semiconductor substrate includes a first area which lacks the first electrodes and a second area in which the first electrodes are positioned,
wherein the lightly doped region and the heavily doped region are positioned in each first area,
wherein the heavily doped region is positioned in each second area,
wherein the first electrodes extend in a first direction in each second area and are connected to the heavily doped region positioned in each second area, and
wherein the lightly doped region and the heavily doped region positioned in the first area are alternately positioned in the first direction and extend in a second direction intersecting the first direction.

15. The solar cell of claim 14, wherein a first direction width of the lightly doped region positioned in the first area is greater than ¼ of a distance between the first electrodes and is less than two times the distance between the first electrodes.

16. The solar cell of claim 14, wherein a first direction width of the heavily doped region positioned in the first area is greater than ¼ of a width of the first electrodes and is less than a distance between the first electrodes.

17. The solar cell of claim 14, wherein a first direction width of the lightly doped region positioned in the first area is equal to or greater than a first direction width of the heavily doped region positioned in the first area.

18. The solar cell of claim 14, further comprising a second conductive region containing impurities of a conductivity type opposite a conductivity type of the impurities of the first conductivity type or the second conductivity type doped on the first conductive region at the opposite surface of the one surface of the semiconductor substrate.

19. The solar cell of claim 18, further comprising a control passivation layer formed between the second conductive region and the semiconductor substrate, the control passivation layer including a dielectric material.

20. The solar cell of claim 19, wherein a thickness of the control passivation layer is 0.5 nm to 2.5 nm.
